(19) United States
(12) Patent Application Publication
(10) Pub. No.: US 2025/0084522 A1
(43) Pub. Date: Mar. 13, 2025

(54) MASK ASSEMBLY, APPARATUS FOR MANUFACTURING DISPLAY DEVICE, AND METHOD OF MANUFACTURING DISPLAY DEVICE

(71) Applicant: Samsung Display Co., Ltd., Yongin-si (KR)

(72) Inventors: Areum Lee, Yongin-si, Gyeonggi-do (KR); Hwi Kim, Yongin-si, Gyeonggi-do (KR); Jungsun Park, Yongin-si, Gyeonggi-do (KR); Jihee Son, Yongin-si, Gyeonggi-do (KR); Seoulki Lee, Yongin-si, Gyeonggi-do (KR); Seungjun Lee, Yongin-si, Gyeonggi-do (KR); Yeonhwa Lee, Yongin-si, Gyeonggi-do (KR); Joongu Lee, Yongin-si, Gyeonggi-do (KR)

(73) Assignee: Samsung Display Co., Ltd., Yongin-si (KR)

(21) Appl. No.: 18/678,194

(22) Filed: May 30, 2024

(30) Foreign Application Priority Data
Sep. 13, 2023 (KR) 10-2023-0122043

(51) Int. Cl. C23C 14/04; H10K 71/16

(52) U.S. Cl. CPC C23C 14/042; H10K 71/166

(57) ABSTRACT

A mask assembly includes a mask frame including a plurality of sides and an opening, a first support stick arranged on the mask frame to overlap the opening, the first mask stick extending in a direction parallel to one of the sides of the mask frame, a mask sheet arranged on the first support stick, the mask sheet extending in a direction parallel to one of the sides of the mask frame, and a first waterproof membrane arranged on a surface of the first support stick facing the mask sheet.

### CROSS-REFERENCE TO RELATED APPLICATIONS

This application claims priority under 35 U.S.C. § 119 from Korean Patent Application No. 10-2023-0122043 filed on Sep. 13, 2023 in the Korean Intellectual Property Office, the entire contents of which are incorporated herein by reference.

### BACKGROUND

### 1. Technical Field

One or more embodiments relate to a mask assembly, an apparatus for manufacturing a display device, the apparatus including the mask assembly, and a method of manufacturing a display device by using the mask assembly.

### 2. Description of the Related Art

Display devices visually display data. Display devices may provide an image by using light-emitting diodes. The use and structures of display devices have diversified, and structures capable of being bent to a certain angle from an approximately flat state have also been developed.

Display devices may include multiple pixels arranged in a pattern to produce an image. In this regard, several layers including an emission layer may be included in the pixels arranged in the pattern. Such layers may be disposed on a substrate in different patterns depending on their types.

### SUMMARY

Each layer of a display device may be formed by spraying a deposition material toward a mask assembly having openings corresponding to a pattern to be formed over a substrate. To remove a deposition material that remains on the mask assembly without passing through the openings, the mask assembly may be cleaned using a cleaning solution. In this regard, a problem may occur where the cleaning solution remains in some narrow gaps of the mask assembly.

Additional aspects will be set forth in part in the description which follows and, in part, will be apparent from the description, or may be learned by practice of the presented embodiments of the disclosure.

According to one or more embodiments, a mask assembly may include a mask frame including a plurality of sides and an opening, a first support stick arranged on the mask frame to overlap the opening, the first support stick extending in a direction parallel to at least one of the plurality of sides of the mask frame, a mask sheet arranged on the first support stick, the mask sheet extending in a direction parallel to one of the plurality of sides of the mask frame, and a first waterproof membrane arranged on a surface of the first support stick facing the mask sheet.

The mask assembly may further include a second support stick arranged between the first support stick and the mask sheet, the second support stick to intersect the first support stick, and a second waterproof membrane arranged on a surface of the second support stick.

The second waterproof membrane may be arranged on a surface of the second support stick that faces the mask sheet.

The first support stick may include a groove overlapping the second support stick, and at least a portion of the second support stick may be arranged in the groove.

The mask assembly may further include an alignment stick arranged on the mask frame, the alignment stick may be adjacent to the mask sheet and parallel to one of the plurality of sides of the mask frame.

The first waterproof membrane may include a self-assembled monolayer.

According to one or more embodiments, an apparatus for manufacturing a display device may include a mask assembly, and a deposition source facing the mask assembly and configured to spray a deposition material toward the mask assembly in a first direction, wherein the mask assembly includes a mask frame including a plurality of sides and an opening, a first support stick arranged on the mask frame to overlap the opening, the first support stick extending in a direction parallel to one of the plurality of sides of the mask frame, a mask sheet arranged on the first support stick, the mask sheet extending in a direction parallel to one of the plurality of sides of the mask frame, and a first waterproof membrane arranged on a surface of the first support stick facing the first direction.

The mask assembly may further include a second support stick arranged between the first support stick and the mask sheet, the second support stick intersecting the first support stick, and a second waterproof membrane arranged on a surface of the second support stick.

The second waterproof membrane may be arranged on a surface of the second support stick that faces the first direction.

In a schematic cross-sectional view, the first support stick, the first waterproof membrane, the second support stick, the second waterproof membrane, and the mask sheet may be sequentially arranged in the first direction.

The first support stick may include a groove overlapping the second support stick, and at least a portion of the second support stick may be arranged in the groove.

The mask assembly may further include an alignment stick arranged on the mask frame, the alignment stick may be adjacent to the mask sheet and parallel to one of the plurality of sides of the mask frame.

The first waterproof membrane may include a self-assembled monolayer.

According to one or more embodiments, a method of manufacturing a display device includes arranging a mask assembly and a deposition source to face a substrate, aligning the mask assembly to the substrate, and depositing a deposition material on the substrate by spraying the deposition material from the deposition source toward the mask assembly in a first direction, wherein the mask assembly may include a mask frame including a plurality of sides and an opening, a first support stick arranged on the mask frame to overlap the opening, the first support stick extending in a direction parallel to one of the plurality of sides of the mask frame, a mask sheet arranged on the first support stick, the mask sheet extending in a direction parallel to one of the plurality of sides of the mask frame, and a first waterproof membrane arranged on a surface of the first support stick facing the first direction.

The mask assembly may further include a second support stick arranged between the first support stick and the mask sheet, the second support stick intersecting the first support stick, and a second waterproof membrane arranged on a surface of the second support stick.

The second waterproof membrane may be arranged on a surface of the second support stick that faces the first direction.

In a schematic cross-sectional view, the first support stick, the first waterproof membrane, the second support stick, the second waterproof membrane, and the mask sheet may be sequentially arranged in the first direction.

The first support stick may include a groove overlapping the second support stick, and at least a portion of the second support stick may be arranged in the groove.

The mask assembly may further include an alignment stick arranged on the mask frame, the alignment stick may be adjacent to the mask sheet and parallel to one of the plurality of sides of the mask frame.

The first waterproof membrane may include a self-assembled monolayer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device according to an embodiment;

FIG. 2 is an exploded perspective view of a mask assembly according to an embodiment;

FIG. 3A is a perspective view of a first support stick according to an embodiment;

FIG. 3B is a perspective view of a second support stick according to an embodiment;

FIG. 4 is an exploded perspective view of a mask assembly, showing first and second support sticks coupled to a mask frame according to an embodiment;

FIG. 5 is a schematic cross-sectional view of the mask assembly taken along line V-V′ of FIG. 4;

FIG. 6A is a schematic cross-sectional view of the mask assembly taken along line VI-VI′ of FIG. 4;

FIG. 6B is another schematic cross-sectional view of the mask assembly taken along line VI-VI′ of FIG. 4;

FIG. 7 is a perspective view of a mask assembly in which a mask sheet and an alignment stick are coupled to a mask frame according to an embodiment;

FIG. 8 is a schematic cross-sectional view of the mask assembly taken along line VIII-VIII′ of FIG. 7;

FIG. 9 is an enlarged schematic cross-sectional view of a portion of a waterproof membrane according to an embodiment;

FIGS. 10A and 10B are schematic cross-sectional views for comparing residual forms of a cleaning solution between a second support stick and a mask sheet according to embodiments;

FIGS. 11A to 11F are schematic cross-sectional views showing a process of manufacturing a mask assembly according to an embodiment;

FIG. 12 is a plan view of a display device manufactured using an apparatus for manufacturing a display device according to an embodiment; and

FIG. 13 is a schematic cross-sectional view of the display device taken along line XIII-XIII′ of FIG. 12.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1, DR2, and DR3 directions are not limited to three axes of a rectangular coordinate system, such as the x, y, and z axes, and may be interpreted in a broader sense. For example, the DR1, DR2, and DR3 directions may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

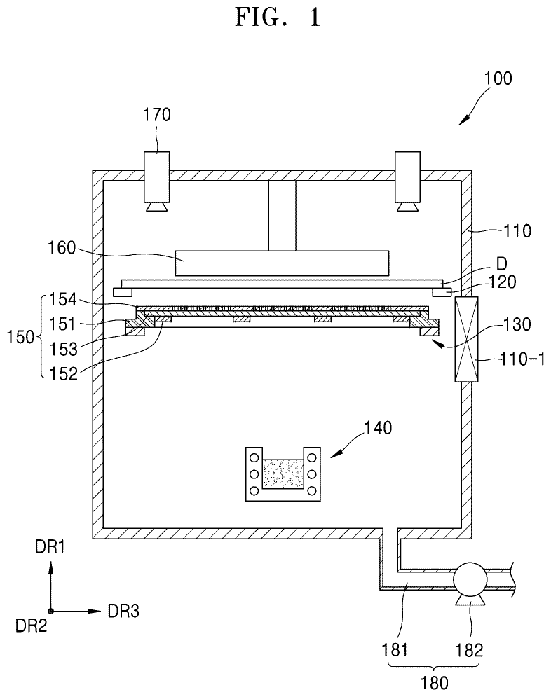

FIG. 1 is a schematic cross-sectional view of an apparatus 100 for manufacturing a display device according to an embodiment.

Referring to FIG. 1, the apparatus 100 may include a chamber 110, a first support 120, a second support 130, a deposition source 140, a mask assembly 150, a magnetic force portion 160, a vision portion 170, and a pressure controller 180.

The chamber 110 may include a space therein, and a portion thereof may be open. In this regard, a gate valve 110-1 may be installed in the open portion of the chamber 110. The open portion of the chamber 110 may be opened or closed according to an operation of the gate valve 110-1.

The first support 120 may have a display substrate D seated thereon to support the display substrate D. In an embodiment, the first support 120 may be in the form of a plate fixed inside the chamber 110. In an embodiment, the first support 120 may have the display substrate D seated thereon and may be in the form of a shuttle linearly moveable in the chamber 110. In an embodiment, the first support 120 may include an electrostatic chuck or adhesive chuck arranged in the chamber 110 to be fixed to the chamber 110 or capable of being raised or lowered in the chamber 110. Hereinafter, a case where the first support 120 is in the form of a plate fixed inside the chamber 110 will be described for convenience.

The mask assembly 150 may be seated on the second support 130. In this regard, the second support 130 may be arranged inside the chamber 110. The second support 130 may fine-adjust a position of the mask assembly 150. In an embodiment, the second support 130 may include a separate driver or alignment part for moving the mask assembly 150 in different directions. In an embodiment, the second support 130 may be in the form of a shuttle. The second support 130 may have the mask assembly 150 seated thereon and may transport the mask assembly 150. For example, the second support 130 may move out of the chamber 110 to have the mask assembly 150 seated thereon and then may enter the chamber 110 from the outside of the chamber 110.

The first support 120 and the second support 130 may be integral with each other. The first support 120 and the second support 130 may include a movable shuttle. In this regard, the first support 120 and the second support 130 may include a structure of fixing the mask assembly 150 and the display substrate D such that the display substrate D is seated on the mask assembly 150, and may linearly move the display substrate D and the mask assembly 150 simultaneously.

Hereinafter, a case in which the first support 120 and the second support 130 are distinct from each other and arranged at different positions and a case in which the first support 120 and the second support 130 are arranged inside the chamber 110 will be described for convenience.

The deposition source 140 may face the mask assembly 150. In this regard, a deposition material may be accommodated in the deposition source 140, and the deposition material may be evaporated or sublimated by heating the deposition material. The deposition source 140 may be fixed inside the chamber 110 or may be arranged inside the chamber 110 to be linearly moveable in a direction. Hereinafter, a case where the deposition source 140 is fixed inside the chamber 110 will be described for convenience.

The mask assembly 150 may include a mask frame 151, first and second support sticks 152 and 153, and a mask sheet 154.

The magnetic force portion 160 may be arranged inside the chamber 110 to face the display substrate D. In this regard, the magnetic force portion 160 may apply magnetic force to the mask sheet 154, thereby pressing the mask assembly 150 toward the display substrate D. In particular, the magnetic force portion 160 may prevent the mask sheet 154 from sagging down and may also bring the mask sheet 154 into close contact with the display substrate D. The magnetic force portion 160 may maintain a uniform space between the mask sheet 154 and the display substrate D with respect to a length direction of the mask sheet 154.

The vision portion 170 may be installed at the chamber 110 and may capture images of positions of the display substrate D and the mask assembly 150. In this regard, the vision portion 170 may include a camera for capturing images of the display substrate D and the mask assembly 150. Positions of the display substrate D and the mask assembly 150 may be identified based on the images captured by the vision portion 170, and based on the images, the first support 120 may fine-adjust the position of the display substrate D or the second support 130 may fine-adjust the position of the mask assembly 150. Hereinafter, a case where the second support 130 fine-adjusts a position of the mask assembly 150 to align positions of the display substrate D and the mask assembly 150 with each other will be described.

The pressure controller 180 may be connected to the chamber 110 to control the internal pressure of the chamber 110. For example, the pressure controller 180 may adjust the internal pressure of the chamber 110 to a level that is the same as or similar to that of atmospheric pressure. The pressure controller 180 may adjust the internal pressure of the chamber 110 to a level that is the same as or similar to that of a vacuum state.

The pressure controller 180 may include a connection pipe 181 connected to the chamber 110 and a pump 182 installed at the connection pipe 181. In this regard, depending on an operation of the pump 182, external air may flow in through the connection pipe 181 or gas inside the chamber 110 may be guided to the outside through the connection pipe 181.

The above apparatus 100 may be used to manufacture a display device described below. First, in case that the pressure controller 180 adjusts pressure of the inside of the chamber 110 to a level that is the same as or similar to atmospheric pressure, the gate valve 110-1 may operate to open the opened portion of the chamber 110.

After that, the display substrate D may be inserted into the chamber 110 from the outside of the chamber 110. In this regard, the display substrate D may be inserted into the chamber 110 in various ways. For example, the display substrate D may be inserted into the chamber 110 from the outside of the chamber 110 through a robot arm, etc., arranged outside the chamber 110. In an embodiment, in case that the first support 120 is in the form of a shuttle, the first support 120 may be carried out of the chamber 110 from the inside of the chamber 110, and then, the display substrate D may be seated on the first support 120 through a separate robot arm, etc., arranged outside the chamber 110, and the first support 120 may be inserted into the chamber 110 from the outside of the chamber 110. Hereinafter, a case where the display substrate D is inserted into the chamber 110 from the outside of the chamber 110 through a robot arm arranged outside the chamber 110 will be described for convenience.

As described above, the mask assembly 150 may be arranged inside the chamber 110. In an embodiment, in the same or similar manner as the display substrate D, the mask assembly 150 may be inserted into the chamber 110 from the outside of the chamber 110. Hereinafter, a case where only the display substrate D is inserted into the chamber 110 from the outside of the chamber 110 with the mask assembly 150 arranged inside the chamber 110 will be described for convenience.

In an embodiment, the first support 120 and the second support 130 may be in the form of a shuttle, and the display substrate D and the mask assembly 150 may be fixed and then may be inserted into the chamber 110 from the outside of the chamber 110.

In case that the display substrate D is inserted into the chamber 110, the display substrate D may be seated on the first support 120. In this regard, the vision portion 170 may capture images of positions of the display substrate D and the mask assembly 150. In particular, the vision portion 170 may capture images of a first alignment mark of the display substrate D and a second alignment mark of the mask assembly 150.

Based on the captured images of the first alignment mark and the second alignment mark, positions of the display substrate D and the mask assembly 150 may be identified. In this regard, the apparatus 100 may include a separate controller to identify positions of the display substrate D and the mask assembly 150.

In case that positions of the display substrate D and the mask assembly 150 have been identified, the second support 130 may fine-adjust the position of the mask assembly 150.

After that, the deposition source 140 may operate to spray a deposition material toward the mask assembly 150 (e.g., in the first direction DR1), and the deposition material passing through multiple openings of the mask sheet 154 may be deposited on the display substrate D. In this regard, the pump 182 may suck gas from inside the chamber 110 and discharge the gas to the outside, thereby maintaining the internal pressure of the chamber 110 at a level that is the same as or similar to that of a vacuum state.

The deposition material may be deposited on the display substrate D by passing through an opening arranged in a deposition area (not shown). In this regard, the mask assembly 150 may provide a deposition area that is the same as or similar to a designed deposition area.

The above operation may be repeatedly performed on multiple display substrates D. In this regard, in case that the number of depositions on the display substrates D is equal to a preset number of depositions, the apparatus 100 may stop operating, and the mask assembly 150 may be drawn out of the chamber 110.

The deposition material used during deposition may be deposited on the mask assembly 150. In particular, in case that the deposition material is deposited in the openings of the mask sheet 154, the deposition material may not be deposited on the display substrate D as much as a pre-designed area, and thus precise deposition may be difficult. The above problem may be solved by cleaning the deposition material adsorbed on an outer surface of the mask assembly 150 and/or an inner surface of the openings of the mask sheet 154.

Accordingly, the apparatus 100 may allow the deposition of a deposition material on an area that is the same as or similar to a shape designed on the display substrate D. The apparatus 100 may allow the deposition of a deposition material in a precise pattern and thus may allow the manufacture of a display device capable of precise image implementation.

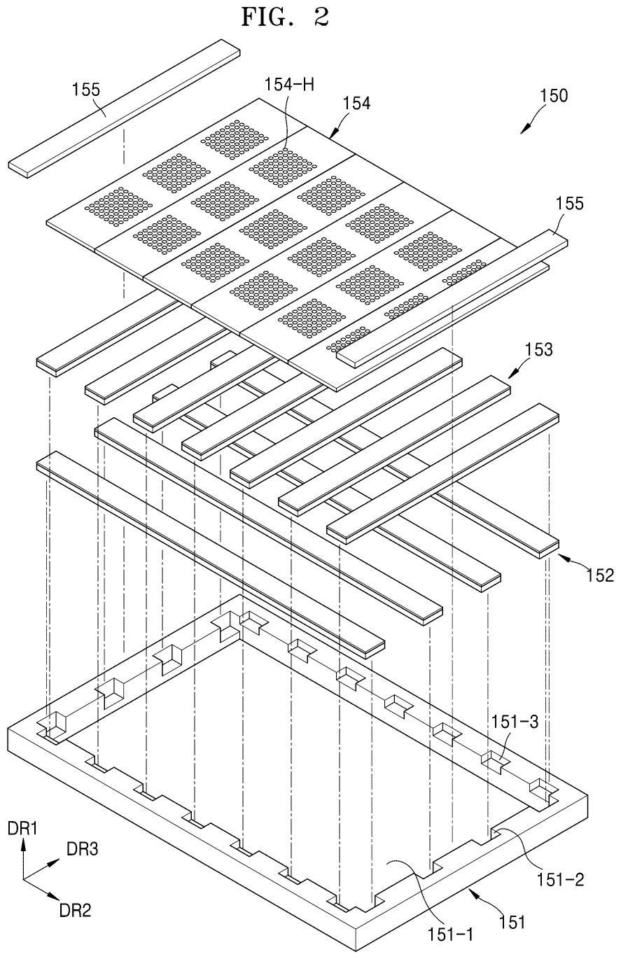

FIG. 2 is an exploded perspective view of the mask assembly 150 according to an embodiment.

Referring to FIG. 2, the mask assembly 150 may include the mask frame 151, the first and second support sticks 152 and 153, and the mask sheet 154.

The mask frame 151 may have multiple frames connected to one another to form a space inside. In an embodiment, the mask frame 151 may be in the form of a frame with one opening 151-1 formed in the center. In an embodiment, the mask frame 151 may be in a grid shape such as a window frame including multiple openings. Hereinafter, a case where the mask frame 151 includes one opening 151-1 in the center will be described for convenience. In this regard, a length of a side (or a long side) of the mask frame 151 may be greater than that of another side (or a short side) thereof. In an embodiment, in case that a side of the mask frame 151 extending in the second direction DR2 is defined as a long side, and a side of the mask frame 151 extending in the third direction DR3 is defined as a short side, a length of the long side may be greater than that of the short side.

The mask frame 151 may include a first groove 151-2 and a second groove 151-3 in a surface thereof (e.g., a surface facing the first direction DR1). The first and second grooves 151-2 and 151-3 do not penetrate the mask frame 151 and may be arranged at regular intervals. For example, the first groove 151-2 may include multiple first grooves 151-2, may be spatially connected to the opening 151-1 of the mask frame 151, and may be arranged in the third direction DR3. Similarly, the second groove 151-3 may include multiple second grooves 151-3, may be spatially connected to the opening 151-1 of the mask frame 151, and may be arranged in the second direction DR2. The first and second grooves 151-2 and 151-3 may provide spaces into which both ends of the first and second support sticks 152 and 153 respectively may be inserted to be fixed to the mask frame 151.

The first and second support sticks 152 and 153 may be disposed on the mask frame 151. In this regard, each of the first and second support sticks 152 and 153 may be provided in multiple numbers and may be disposed on the mask frame 151 to be apart from another. For example, each of multiple first support sticks 152 and multiple second support sticks 153 may be spaced apart and parallel to a side of the mask sheet 154. In an embodiment, the first support stick 152 may extend in the second direction DR2 and may be arranged in the third direction DR3. The first support stick 152 may be parallel to the long side of the mask frame 151. The second support stick 153 may extend in the third direction DR3 and may be arranged in the second direction DR2. The second support stick 153 may be parallel to the short side of the mask frame 151. In an embodiment, the first support stick 152 may be omitted, and only the second support stick 153 may be disposed on the mask frame 151. In an embodiment, the second support stick 153 may be omitted, and only the first support stick 152 may be disposed on the mask frame 151. Although FIG. 2 shows four first support sticks 152 and seven second support sticks 153, one or more embodiments are not necessarily limited to the numbers of first and second support sticks 152 and 153.

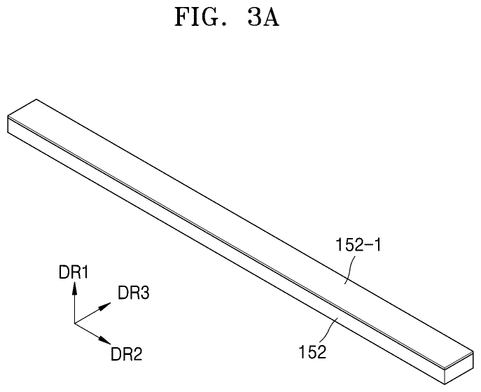

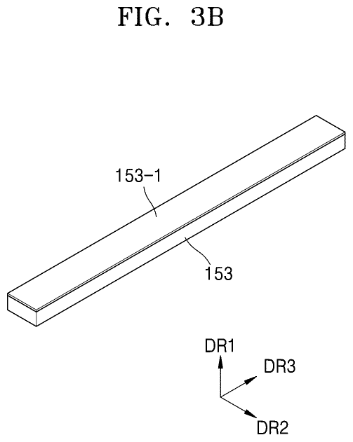

FIG. 3A is a perspective view of the first support stick 152 according to an embodiment.

Referring to FIG. 3A, a first waterproof membrane 152-1 may be disposed on a surface of the first support stick 152. For example, the first waterproof membrane 152-1 may be disposed on a surface facing the first direction DR1 among surfaces of the first support stick 152. In other words, the first waterproof membrane 152-1 may be disposed on a surface facing away from a deposition material sprayed by the deposition source 140 (of FIG. 1) among surfaces of the first support stick 152.

FIG. 3B is a perspective view of the second support stick 153 according to an embodiment.

Referring to FIG. 3B, in a similar way as the first support stick 152, a second waterproof membrane 153-1 may be disposed on a surface of the second support stick 153. For example, the second waterproof membrane 153-1 may be disposed on a surface facing the first direction DR1 among surfaces of the second support stick 153. In other words, the second waterproof membrane 153-1 may be disposed on a surface facing away from a deposition material sprayed by the deposition source 140 (of FIG. 1) among surfaces of the second support stick 153. In various embodiments, unless otherwise specified, it will be understood that the first and second waterproof membranes 152-1 and 153-1 are disposed on the first and second support sticks 152 and 153 respectively.

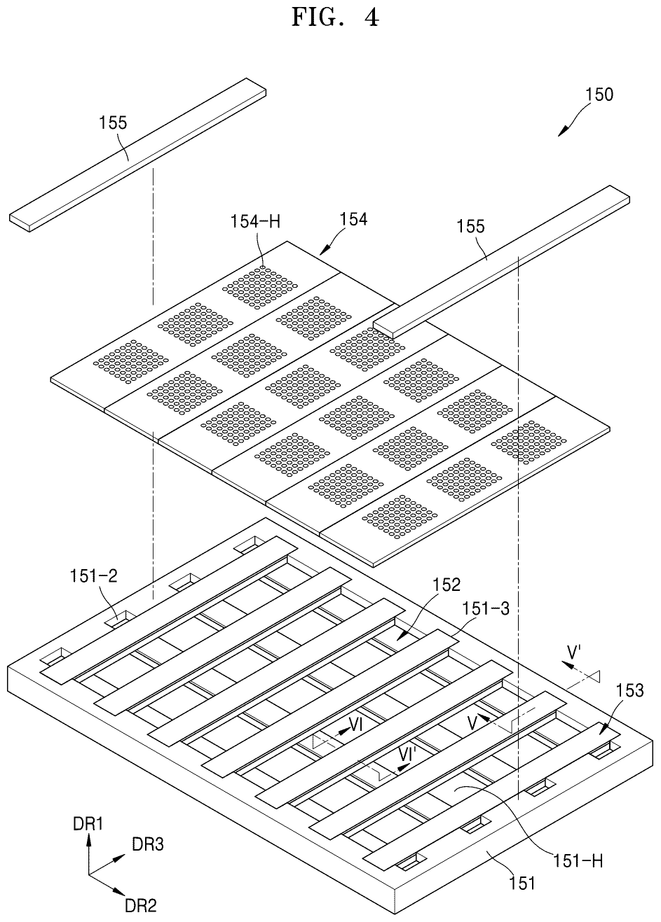

FIG. 4 is an exploded perspective view of the mask assembly 150, showing the first and second support sticks 152 and 153 coupled to the mask frame 151 according to an embodiment.

Referring to FIG. 4, the first and second support sticks 152 and 153 may be coupled to the mask frame 151. In an embodiment, the first support stick 152 may have both ends respectively inserted into first grooves 151-2 of the mask frame 151 facing each other and thus may be coupled to the mask frame 151. Similarly, the second support stick 153 may have both ends respectively inserted into second grooves 151-3 of the mask frame 151 facing each other and thus may be coupled to the mask frame 151. In an embodiment, unlike that shown in FIG. 4, the first and second grooves 151-2 and 151-3 may be omitted, and the first and second support sticks 152 and 153 may be welded to a surface (e.g., a surface facing the first direction DR1) of the mask frame 151.

The first support stick 152 and the second support stick 153 coupled to the mask frame 151 may partition the opening 151-1 of the mask frame 151 into multiple holes 151-H. The holes 151-H defined by the first support stick 152 and the second support stick 153 may define deposition areas through which a deposition material to be deposited on the display substrate D passes.

The mask sheet 154 may include at least one mask sheet 154. In case that the mask sheet 154 includes at least two mask sheets 154, the at least two mask sheets 154 may extend in a direction (e.g., the third direction DR3) and may be arranged in another direction (e.g., the second direction DR2). A side of the mask sheet 154 extending in the third direction DR3 may be understood as a long side of the mask sheet 154, and a side of the mask sheet 154 extending in the second direction DR2 may be understood as a short side of the mask sheet 154. In some embodiments, the first support stick 152 extending in the second direction DR2 may intersect multiple mask sheets 154, and the second support stick 153 extending in the third direction DR3 may overlap two mask sheets 154 adjacent to each other at a same time.

The mask sheet 154 may include at least one hole 154-H. For example, multiple holes 154-H may be formed in the mask sheet 154 in a length direction (e.g., the third direction DR3) of the mask sheet 154. In this regard, the holes 154-H may be apart from each other by a certain distance in a direction (e.g., the second direction DR2) and may penetrate the mask sheet 154. In some embodiments, the holes 154-H in the mask sheet 154 may overlap each of the holes 151-H defined by the first and second support sticks 152 and 153. In some embodiments, the holes 154-H may not be formed in the mask sheet 154 in an area overlapping the first and second support sticks 152 and 153.

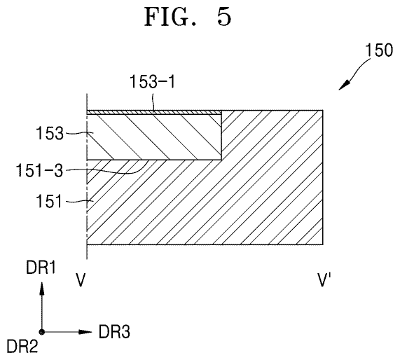

FIG. 5 is a schematic cross-sectional view of the mask assembly 150 taken along line V-V′ of FIG. 4.

Referring to FIG. 5, a portion of the second support stick 153 may be arranged in the second groove 151-3 of the mask frame 151.

The second waterproof membrane 153-1 may be disposed on the second support stick 153. Because the second waterproof membrane 153-1 may be disposed on a surface of the second support stick 153 facing the first direction DR1, the second support stick 153 may be in contact (e.g., direct contact) with the mask frame 151 in the second groove 151-3. Although FIG. 5 shows an upper surface of the second waterproof membrane 153-1 being coplanar (or flush) with an upper surface of the mask frame 151, one or more embodiments are not limited thereto. In an embodiment, an upper surface of the second support stick 153 may coincide with an upper surface of the mask frame 151, and the second waterproof membrane 153-1 may protrude beyond the upper surface of the mask frame 151. In an embodiment, an upper surface of the second support stick 153 may protrude beyond an upper surface of the mask frame 151.

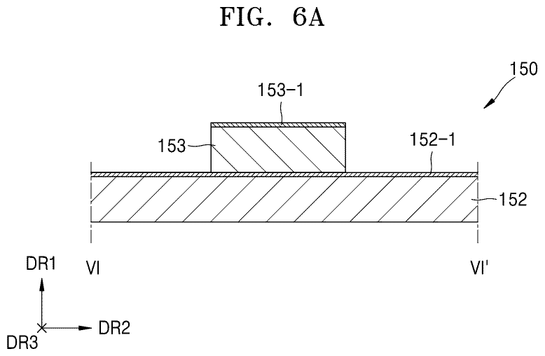

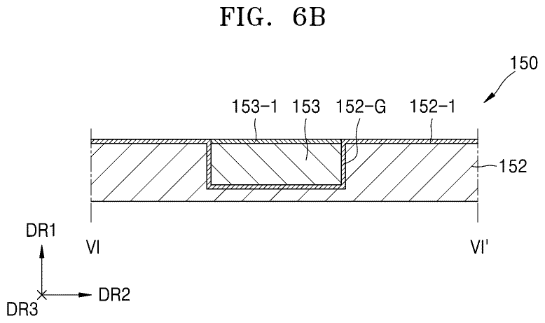

FIG. 6A is a schematic cross-sectional view of the mask assembly 150 taken along line VI-VI′ of FIG. 4.

Referring to FIG. 6A, the second support stick 153 may be disposed on the first support stick 152. The first waterproof membrane 152-1 may be disposed between the first and second support sticks 152 and 153. The second waterproof membrane 153-1 may be disposed on the second support stick 153. In other words, the first support stick 152, the first waterproof membrane 152-1, the second support stick 153, and the second waterproof membrane 153-1 may be sequentially arranged in the first direction DR1 (or a deposition direction). Although FIG. 6A shows the first waterproof membrane 152-1 being in contact (e.g., direct contact) with the second support stick 153, one or more embodiments are not limited thereto. In an embodiment, the first waterproof membrane 152-1 and the second support stick 153 may be apart from each other. In another example, the first waterproof membrane 152-1 and the second support stick 153 may be in contact (e.g., direct contact) with each other in some areas and apart from each other in other areas.

FIG. 6B is another schematic cross-sectional view of the mask assembly 150 of FIG. 4, taken along line VI-VI′ of FIG. 4.

Referring to FIG. 6B, the first support stick 152 may include a groove 152-G in an area overlapping the second support stick 153. A portion of the first waterproof membrane 152-1 may be arranged in the groove 152-G. A portion of the second support stick 153 and the second waterproof membrane 153-1 may be arranged in the groove 152-G. Although FIG. 6B shows an upper surface of the second waterproof membrane 153-1 being coplanar (or flush) with an upper surface of the first waterproof membrane 152-1, one or more embodiments are not limited thereto. In an embodiment, an upper surface of the second support stick 153 may coincide with an upper surface of the first waterproof membrane 152-1, and the second waterproof membrane 153-1 may protrude beyond the upper surface of the first waterproof membrane 152-1. In an embodiment, an upper surface of the second support stick 153 may protrude beyond an upper surface of the first waterproof membrane 152-1. Similar to the case of FIG. 6A, the first waterproof membrane 152-1 and the second support stick 153 may be apart from each other, or may be in contact (e.g., direct contact) with each other in some areas and apart from each other in other areas.

In the embodiment described with reference to FIGS. 6A and 6B, in case that the first and second support sticks 152 and 153 are apart from each other and there is a gap therebetween, a cleaning solution may remain in the gap during a process of cleaning the mask assembly 150. In this regard, the first waterproof membrane 152-1 may include a hydrophobic material and thus may reduce an amount of residual cleaning solution.

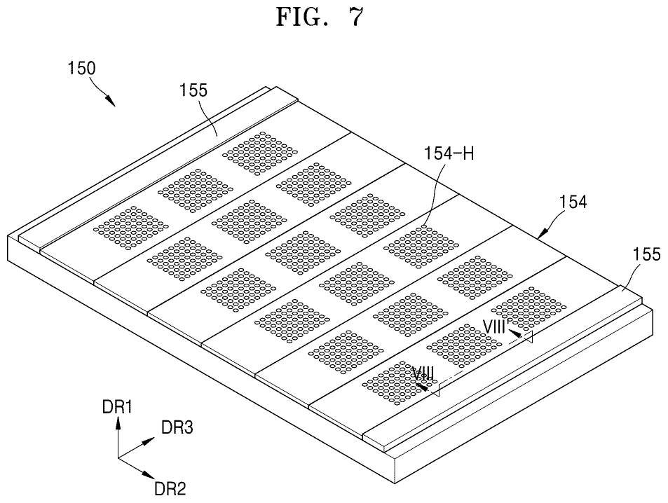

FIG. 7 is a perspective view of the mask assembly 150 in which the mask sheet 154 and an alignment stick 155 are coupled to the mask frame 151 according to an embodiment.

Referring to FIG. 7, the mask sheet 154 may be coupled onto the mask frame 151. For example, the mask sheet 154 may be welded on an upper surface (or a surface facing the first direction DR1) of the mask frame 151. Mask sheets 154 may be in contact (e.g., direct contact) with or apart from each other. In case that mask sheets 154 are apart from each other, a portion of the second support stick 153 (of FIG. 4) may be exposed in the spaced area.

An edge of the mask sheets 154 and an edge of the mask frame 151 may be in contact with each other. In an embodiment, an edge of the mask sheet 154 extending in the second direction DR2 (e.g., a short side of the mask sheet 154) and an edge of the mask frame 151 extending in the second direction DR2 (e.g., a long side of the mask frame 151) may be in contact with each other and may be coplanar with each other.

The alignment stick 155 may be arranged on a side of an outermost mask sheet 154. In an embodiment, an alignment stick 155 extending in the third direction DR3 may be arranged on a second direction DR2 side of an outermost mask sheet 154 in the second direction DR2 among multiple mask sheets 154. In addition, an alignment stick 155 extending in the third direction DR3 may be arranged on a side opposite to the second direction DR2 of an outermost mask sheet 154 in a direction opposite to the second direction DR2 among the mask sheets 154. The alignment stick 155 may be in contact (e.g., direct contact) with or apart from the mask sheet 154. The alignment stick 155 may serve as the second alignment mark of the mask assembly 150 described above with reference to FIG. 1.

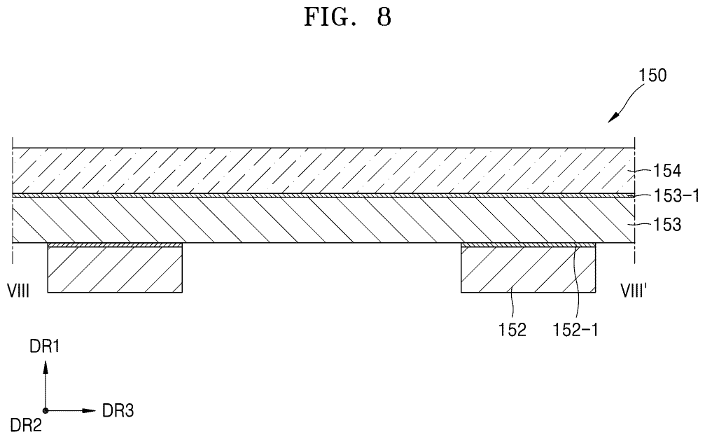

FIG. 8 is a schematic cross-sectional view of the mask assembly 150 taken along line VIII-VIII′ of FIG. 7.

Referring to FIG. 8, the first support stick 152, the first waterproof membrane 152-1, the second support stick 153, the second waterproof membrane 153-1, and the mask sheet 154 may be sequentially arranged in the first direction DR1. The holes 154-H (of FIG. 7) may not be arranged in the mask sheet 154 in an area overlapping the second support stick 153.

Although FIG. 8 shows the mask sheet 154 being in contact (e.g., direct contact) with the second waterproof membrane 153-1 and the second support stick 153 being in contact (e.g., direct contact) with the first waterproof membrane 152-1, one or more embodiments are not limited thereto. In an embodiment, the mask sheet 154 may be apart from the second waterproof membrane 153-1, or may be in contact with the second waterproof membrane 153-1 in some areas and apart from the second waterproof membrane 153-1 in other areas. The second support stick 153 may be apart from the first waterproof membrane 152-1, or may be in contact with the first waterproof membrane 152-1 in some areas and apart from the first waterproof membrane 152-1 in other areas. In case that the mask assembly 150 is cleaned, a portion of cleaning solution may remain between the mask sheet 154 and the second support stick 153 and/or between the second support stick 153 and the first support stick 152. The first and second waterproof membranes 152-1 and 153-1 may include a hydrophobic material and thus may reduce an amount of residual cleaning solution.

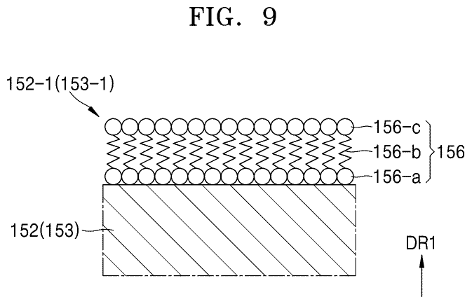

FIG. 9 is an enlarged schematic cross-sectional view of a portion of a waterproof membrane according to an embodiment.

Referring to FIG. 9, the first waterproof membrane 152-1 and/or the second waterproof membrane 153-1 may be formed on the first support stick 152 and/or the second support stick 153. The first and second waterproof membranes 152-1 and 153-1 may include a self-assembled monolayer (SAM) 156. The SAM 156 may include a head portion 156-a, a linker portion 156-b, and a terminal portion 156-c. The head portion 156-a may be in contact (e.g., direct contact) with a surface of the first support stick 152 or the second support stick 153 and may be coupled thereto. The terminal portion 156-c may be apart from the surface of the first support stick 152 or the second support stick 153. The linker portion 156-b may extend between the head portion 156-a and the terminal portion 156-c and may connect the head portion 156-a to the terminal portion 156-c. The head portion 156-a may include a hydrophilic material. The terminal portion 156-c may include a hydrophobic material. The linker portion 156-b may include various types of polymer chains that may be connected to the head portion 156-a and the terminal portion 156-c.

The SAM 156 may be integrally formed on the first support stick 152 and/or the second support stick 153 and may be formed through various processes such as a deposition process and a solution process. In some embodiments, the SAM 156 may include one or more selected from fluoroctatrichlorosilane (FOTS), trichlorooctadecylsilane (OTS), and dichlorodimethylsilane (DDMS).

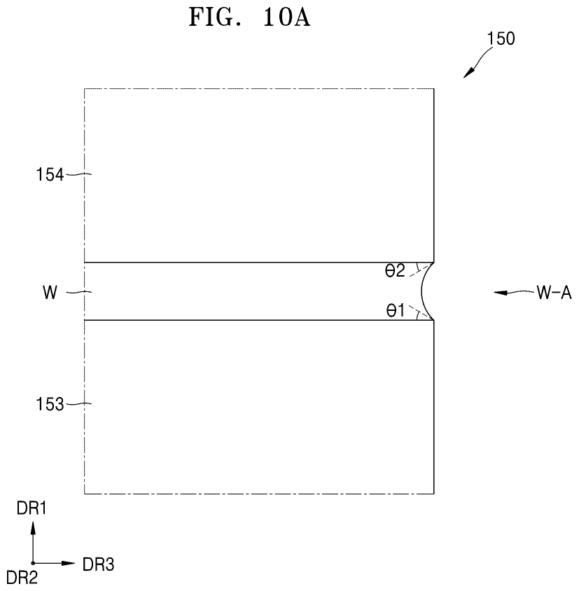

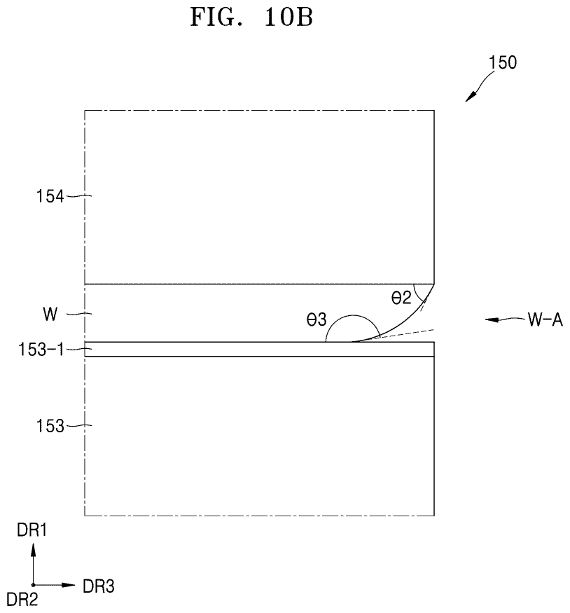

FIGS. 10A and 10B are schematic cross-sectional views for comparing residual forms of a cleaning solution between the second support stick 153 and the mask sheet 154 according to embodiments. The embodiment shown in FIG. 10A is a comparative example in which a second waterproof membrane is omitted. The embodiment shown in FIG. 10B is an embodiment in which a second waterproof membrane is included.

Referring to FIGS. 10A and 10B, there may be some gaps W-A between the second support stick 153 and the mask sheet 154, and a portion of cleaning solution W may remain in the gaps after the mask assembly 150 is cleaned. In this regard, depending on the presence or absence of the second waterproof membrane 153-1, surface tension may be different, and a surface shape of the cleaning solution W may be different.

For example, referring to FIG. 10A, because the second waterproof membrane 153-1 is not arranged, a surface of the second support stick 153 and a surface of the mask sheet 154 may both be hydrophilic. Accordingly, surface tension of the cleaning solution W may be strong on both the surface of the second support stick 153 and the surface of the mask sheet 154. A first contact angle θ1 between the cleaning solution W and the surface of the second support stick 153 may be less than 90°. A second contact angle θ2 between the cleaning solution W and the surface of the mask sheet 154 may be less than 90°. Accordingly, the edge of the cleaning solution W may be concave in a direction (e.g., a direction opposite to the third direction DR3) from the edges of the second support stick 153 and the mask sheet 154. This high surface tension and resulting surface shape makes it difficult to remove residual cleaning solution W and prolongs the time it takes to completely dry the mask assembly 150 after cleaning. In another example, when drying is performed for the same amount of time, a portion of the cleaning solution W may remain in the mask assembly 150, which may cause degradation of deposition quality in case that the mask assembly 150 is used in a subsequent deposition process.

Referring to FIG. 10B, the second waterproof membrane 153-1 may be disposed on the second support stick 153, and thus, the cleaning solution W may be in contact (e.g., direct contact) with the second waterproof membrane 153-1. Referring to FIG. 9 together, the terminal portion 156-c of the SAM 156 may be at an outer surface of the second waterproof membrane 153-1 (e.g., a surface apart from the second support stick 153). Accordingly, the cleaning solution W may be stated to be in contact (e.g., direct contact) with the terminal portion 156-c. The terminal portion 156-c may include a hydrophobic material and thus may have low surface tension in relation to the cleaning solution W. Accordingly, a third contact angle θ3 between the cleaning solution W and the second waterproof membrane 153-1 may be greater than 90°. Surface tension of the cleaning solution W on a lower surface of the cleaning solution W or a surface of the cleaning solution W facing a direction opposite to the first direction DR1 may be lower in the embodiment shown in FIG. 10B than in the embodiment shown in FIG. 10A. Accordingly, in the embodiment shown in FIG. 10B, an amount of the cleaning solution W remaining between the mask sheet 154 and the second support stick 153 due to surface tension may be less than that in the embodiment shown in FIG. 10A. Accordingly, it may also be easier to dry the cleaning solution W in the embodiment shown in FIG. 10B than in the embodiment shown in FIG. 10A. As a result, the second waterproof membrane 153-1 may be disposed on the second support stick 153 to reduce an amount of the residual cleaning solution W and prevent degradation of deposition quality due to the residual cleaning solution W during a subsequent deposition process using the mask assembly 150.

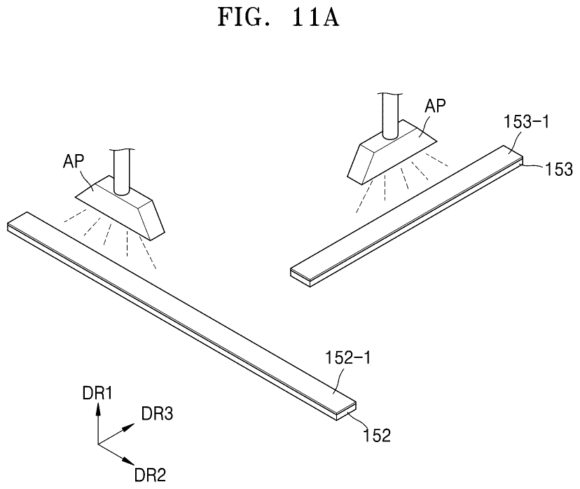

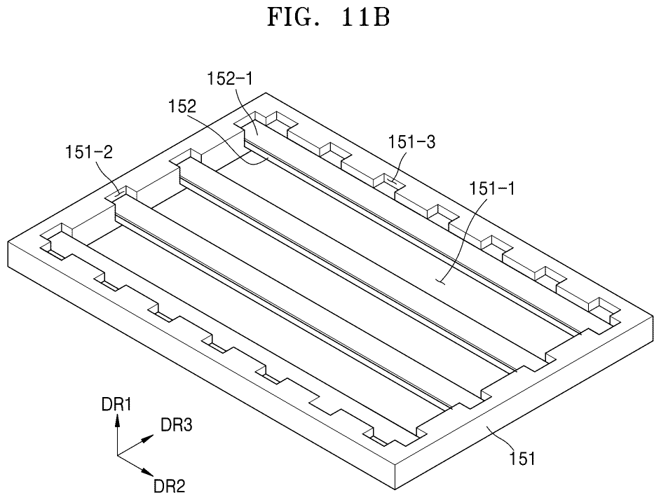

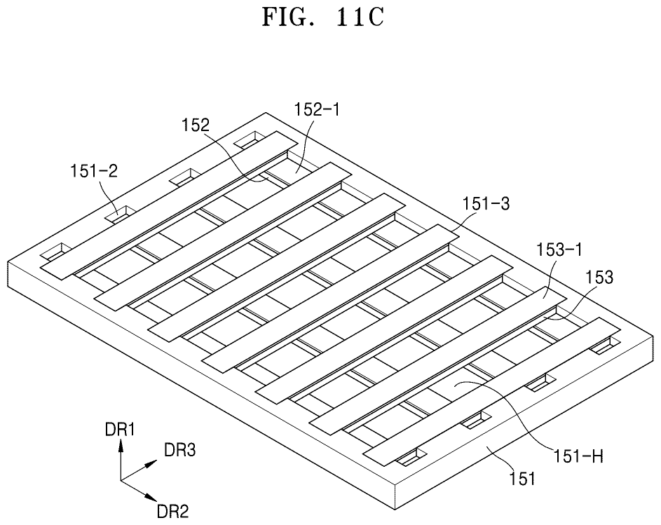

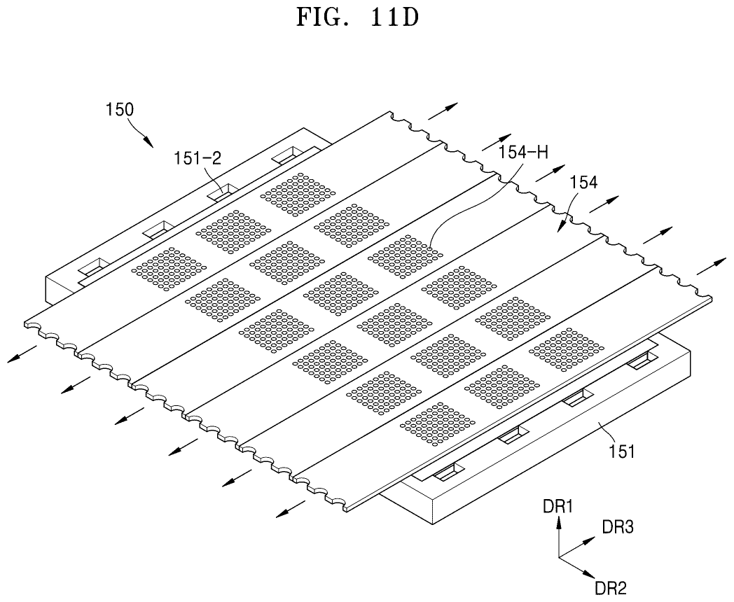

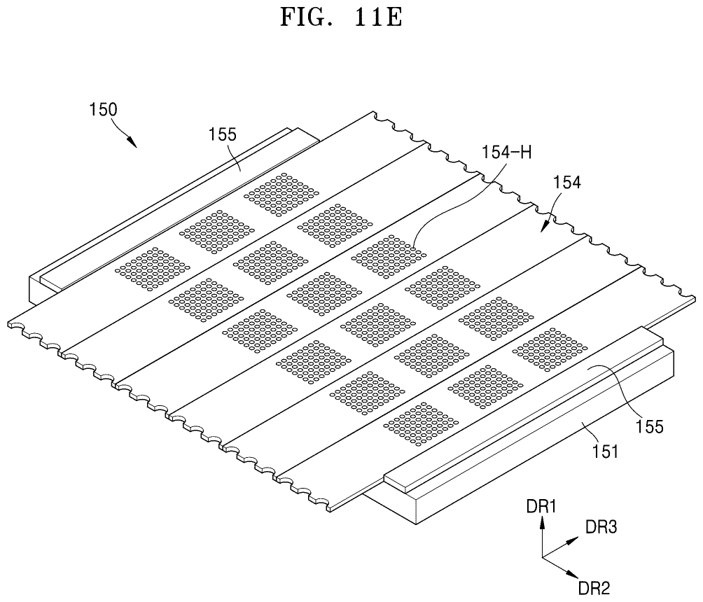

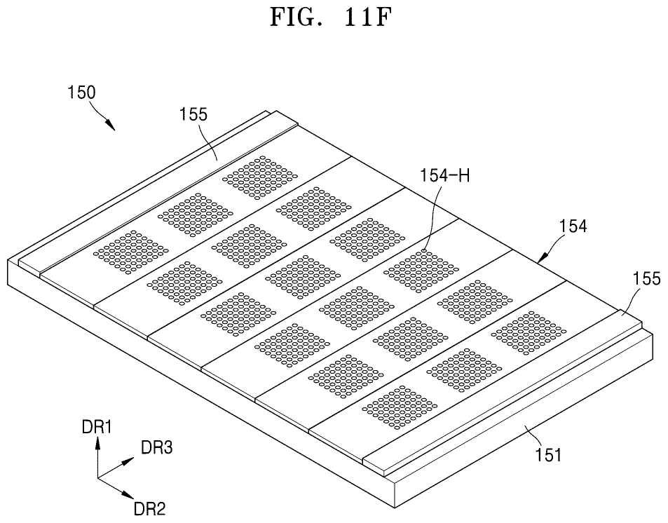

FIGS. 11A to 11E are schematic cross-sectional views showing operations in a process of manufacturing the mask assembly 150 according to an embodiment.

Referring to FIG. 11A, the first waterproof membrane 152-1 and the second waterproof membrane 153-1 may be formed on a surface of the first support stick 152 and a surface of the second support stick 153, respectively. For example, the first waterproof membrane 152-1 may be formed on a surface of the first support stick 152 facing the first direction DR1. The second waterproof membrane 153-1 may be formed on a surface of the second support stick 153 facing the first direction DR1. The first and second waterproof membranes 152-1 and 153-1 may include a same material. Although the first and second waterproof membranes 152-1 and 153-1 may be deposited on the first and second support sticks 152 and 153 respectively by using deposition equipment AP, one or more embodiments may not be limited thereto.

Referring to FIG. 11B, first support sticks 152 may be coupled to the mask frame 151. The first support stick 152 may include multiple first support sticks 152, and each of the first support sticks 152 may be arranged parallel to a long side (or a side extending in the second direction DR2) of the mask frame 151. After that, the first support sticks 152 may be pushed in in a direction opposite to the first direction DR1 to insert both ends of each of the first support sticks 152 into corresponding first grooves 151-2 of the mask frame 151. The first groove 151-2 may be shaped to perfectly fit the end of the first support stick 152. The first support stick 152 may be welded to the first groove 151-2.

Referring to FIG. 11C, second support sticks 153 may be disposed on the structure shown in FIG. 11B. The second support sticks 153 may be coupled to the mask frame 151. The second support stick 153 may include multiple second support sticks 153, and each of the second support sticks 153 may be arranged parallel to a short side (or a side extending in the third direction DR3) of the mask frame 151. After that, the second support sticks 153 may be pushed in in a direction opposite to the first direction DR1 to insert both ends of each of the second support sticks 153 into corresponding second grooves 151-3 of the mask frame 151. The second groove 151-3 may be shaped to perfectly fit an end of the second support stick 153. A depth (or a length in the first direction DR1) of the second groove 151-3 may be less than a depth (or a length in the first direction DR1) of the first groove 151-2. The second support stick 153 may intersect the first support stick 152, and a portion of the second support stick 153 may overlap a portion of the first support stick 152. The second support stick 153 may be welded to the second groove 151-3. The first and second support sticks 152 and 153 may intersect each other and may define the holes 151-H.

Referring to FIG. 11D, the mask sheet 154 may be disposed on the structure shown in FIG. 11C. The mask sheet 154 may be disposed on the mask frame 151 while being tensioned by applying a certain force in a direction (e.g., the third direction DR3 and the opposite direction) to maintain approximate flatness. The mask sheet 154 may include the holes 154-H apart from each other. The mask sheet 154 may be welded to the mask frame 151 so that the mask sheet 154 may be arranged such that the holes 154-H in the mask sheet 154 and the holes 151-H (of FIG. 11C) defined by the first and second support sticks 152 and 153 overlap each other. Because the mask sheet 154 may be welded and fixed to the mask frame 151 while being tensioned, the mask frame 151 may be bent or deformed by a receiving force from the mask sheet 154. In this regard, the first and second support sticks 152 and 153 (of FIG. 11C) may prevent deformation of the mask frame 151 by supporting the mask frame 151. The mask sheet 154 may include multiple mask sheets 154 and may be arranged in a direction (e.g., the second direction DR2) and welded and fixed to the mask frame 151.

Referring to FIG. 11E, the alignment stick 155 may be disposed on the structure shown in FIG. 11D. The alignment stick 155 may extend in a direction (e.g., the third direction DR3) and may be arranged on both sides of the mask sheets 154. For example, the alignment stick 155 may be arranged in the second direction DR2 of the mask sheets 154 and a direction opposite to the second direction DR2. A length of the alignment stick 155 in the third direction DR3 may be the same as that of the short side of the mask frame 151. The alignment stick 155 may be welded and fixed on the mask frame 151.

Referring to FIG. 11F, a portion of the mask sheet 154 may be cut. For example, the mask sheets 154 may be cut along the long side of the mask frame 151 or along the second direction DR2. After cutting, a portion of the mask sheet 154 separated from the mask frame 151 may be removed. Accordingly after cutting, the edge of a short side of the mask sheet 154 may coincide (or be flush with) with the edge of the long side of the mask frame 151.

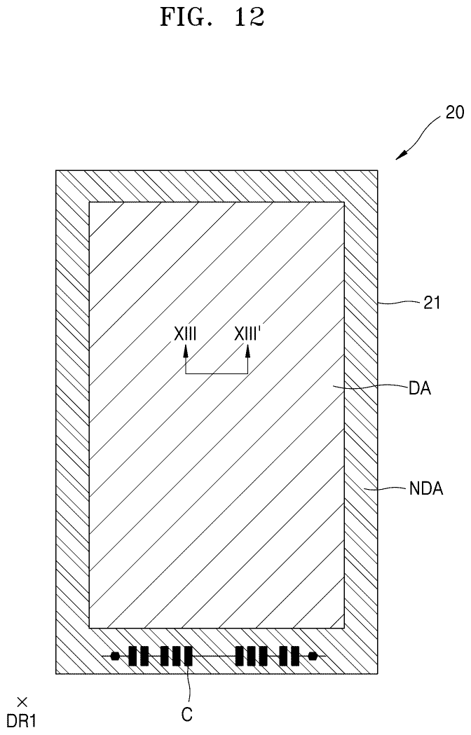

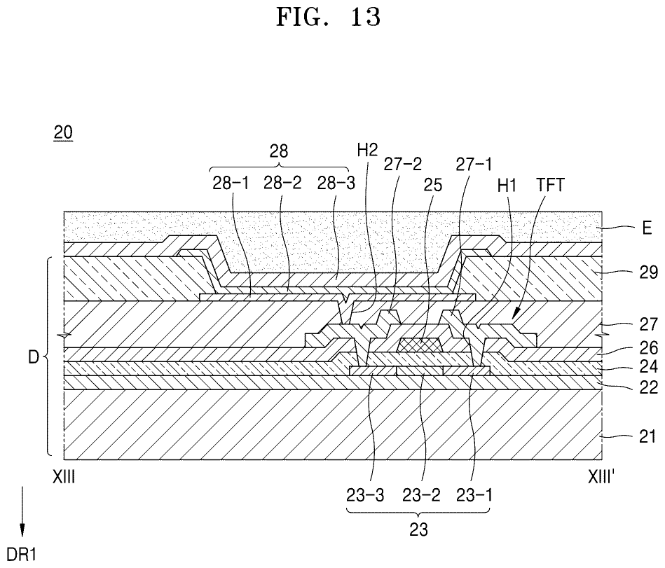

FIG. 12 is a plan view of a display device 20 manufactured using an apparatus for manufacturing a display device according to an embodiment. FIG. 13 is a schematic cross-sectional view of the display device 20 of FIG. 12, taken along line XIII-XIII′ of FIG. 12.

Referring to FIGS. 12 and 13, the display device 20 may have a display area DA and a non-display area NDA defined on a substrate 21, the non-display area NDA may be arranged around the display area DA. A light-emitting element 28 may be arranged in the display area DA, and a power line (not shown), etc. may be arranged in the non-display area NDA. A pad portion C may be arranged in the non-display area NDA.

Multiple deposition material patterns that have passed through the deposition area described above may be arranged in the display area DA. In this regard, the display area DA may have an atypical shape.

The display device 20 may include the display substrate D, an intermediate layer 28-2 disposed on the display substrate D, and an opposite electrode 28-3 disposed on the intermediate layer 28-2. The display device 20 may include a thin-film encapsulation layer E disposed over the opposite electrode 28-3.

The display substrate D may include the substrate 21, a thin-film transistor TFT, a via layer 27, and a pixel electrode 28-1.

The substrate 21 may include a plastic material, or may include a metal material such as SUS, Ti, etc. The substrate 21 may include polyimide (PI).

The thin-film transistor TFT may be disposed over the substrate 21, the via layer 27 may cover the thin-film transistor TFT, and the light-emitting element 28 may be disposed on the via layer 27.

A buffer layer 22 including an organic compound and/or an inorganic compound may be further disposed on an upper surface of the substrate 21, and the buffer layer 22 may contain SiOₓ (x≥1) and/or SiNₓ (x≥1).

After an active layer 23 arranged in a certain pattern is disposed on the buffer layer 22, the active layer 23 may be buried by a gate insulating layer 24. The active layer 23 may include a source region 23-1 and a drain region 23-3 and may further include a channel region 23-2 disposed between the source region 23-1 and the drain region 23-3.

The active layer 23 may contain various materials. In an embodiment, the active layer 23 may contain an inorganic semiconductor material such as amorphous silicon or crystalline silicon. In an embodiment, the active layer 23 may contain an oxide semiconductor. In an embodiment, the active layer 23 may contain an organic semiconductor material. However, a case where the active layer 23 is formed of amorphous silicon will be described below for convenience.

The active layer 23 may be formed by forming an amorphous silicon layer on the buffer layer 22, crystallizing the amorphous silicon layer into a polycrystalline silicon layer, and patterning the polycrystalline silicon layer. The active layer 23 may have the source region 23-1 and the drain region 23-3 doped with impurities depending on the type of a thin-film transistor such as a driving thin-film transistor (not shown), a switching thin-film transistor (not shown), etc.

A gate electrode 25 corresponding to the active layer 23 and an interlayer insulating layer 26 burying the gate electrode 25 may be disposed on an upper surface of the gate insulating layer 24. After a contact hole H1 is formed in the interlayer insulating layer 26 and the gate insulating layer 24, a source electrode 27-1 and a drain electrode 27-2 may be disposed on the interlayer insulating layer 26 to be in contact with the source region 23-1 and the drain region 23-3, respectively.

The via layer 27 is disposed over the thin-film transistor TFT, and the pixel electrode 28-1 of the light-emitting element 28 is disposed on the via layer 27. The pixel electrode 28-1 may be electrically connected to the drain electrode 27-2 of the thin-film transistor TFT by a via hole H2 formed in the via layer 27. The via layer 27 may be formed of an inorganic material and/or an organic material in a single layer or two or more layers, and may be a planarization layer having an approximately flat upper surface regardless of curves in a lower layer thereof or may be curved along curves in a lower layer thereof.

After the pixel electrode 28-1 is disposed on the via layer 27, a pixel-defining layer 29 may be formed of an organic material and/or an inorganic material to cover the pixel electrode 28-1 and the via layer 27 and may have an opening to expose the pixel electrode 28-1.

The intermediate layer 28-2 and the opposite electrode 28-3 may be disposed on the pixel electrode 28-1. In an embodiment, the opposite electrode 28-3 may be disposed over the entire surface of the display substrate D. The opposite electrode 28-3 may be disposed on the intermediate layer 28-2 and the pixel-defining layer 29. Hereinafter, a case where the opposite electrode 28-3 is disposed on the intermediate layer 28-2 and the pixel-defining layer 29 will be described for convenience.

The pixel electrode 28-1 may serve as an anode and the opposite electrode 28-3 may serve as a cathode, and polarities of the pixel electrode 28-1 and the opposite electrode 28-3 may be reversed.

The pixel electrode 28-1 and the opposite electrode 28-3 may be insulated from each other by the intermediate layer 28-2, and voltages of different polarities may be applied to the intermediate layer 28-2 to cause light emission from the organic emission layer.

The intermediate layer 28-2 may include an organic emission layer. As another optional example, the intermediate layer 28-2 may include an organic emission layer, and may further include at least one of a hole injection layer, a hole transport layer, an electron transport layer, and an electron injection layer. The embodiment is not limited thereto, and the intermediate layer 28-2 may include an organic emission layer and may further include various other functional layers (not shown).

In this regard, the intermediate layer 28-2 may be formed through the above-described apparatus for manufacturing a display device. The intermediate layer 28-2 may include multiple intermediate layers 28-2, and the intermediate layers 28-2 may form the display area DA. In this regard, the intermediate layers 28-2 may be apart from each other in the display area DA.

One unit pixel is made up of multiple sub-pixels, and the sub-pixels may emit light of various colors. For example, the sub-pixels may include sub-pixels that emit red light, green light, and blue light, respectively, and may include sub-pixels (not denoted) that emit red light, green light, blue light, and white light.

The sub-pixel described above may include an intermediate layer 28-2. In this regard, in case that a sub-pixel is formed, the intermediate layer 28-2 may be formed through the above-described apparatus for manufacturing a display device.

The thin-film encapsulation layer E may include multiple inorganic layers or may include an inorganic layer and an organic layer. The organic layer of the thin-film encapsulation layer E may be formed of a polymer, and more particularly, may be a single layer or a laminated layer formed of one or more of polyethylene terephthalate, polyimide, polycarbonate, epoxy, polyethylene, and polyacrylate. The inorganic layer of the thin film encapsulation layer E may be a single layer or a laminated layer including metal oxide or metal nitride. More particularly, the inorganic layer may include one or more of SiNₓ, Al₂O₃, SiO₂, and TiO₂. An externally exposed top layer of the thin-film encapsulation layer E may be an inorganic layer for preventing penetration of moisture into a light-emitting element.

The thin-film encapsulation layer E may include at least one sandwich structure with at least one organic layer between at least two inorganic layers. As another example, the thin-film encapsulation layer E may include at least one sandwich structure with at least one inorganic layer between at least two organic layers. As another example, the thin-film encapsulation layer E may include a sandwich structure with at least one organic layer between at least two inorganic layers and a sandwich structure with at least one inorganic layer between at least two organic layers.

According to one or more of the above embodiments, a mask assembly may be implemented in which cleaning solution residue may be reduced by arranging a waterproof membrane in a gap between a mask sheet and a support stick and between support sticks at locations particularly vulnerable to cleaning solution residue. An apparatus for manufacturing a display device, the apparatus including the mask assembly, and a method of manufacturing a display device by using the mask assembly may be implemented to manufacture a display device with improved panel lifespan. However, one or more embodiments are not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A mask assembly comprising:
a mask frame comprising a plurality of sides and an opening;
a first support stick arranged on the mask frame to overlap the opening, the first support stick extending in a direction parallel to at least one of the plurality of sides of the mask frame;
a mask sheet arranged on the first support stick, the mask sheet extending in a direction parallel to one of the plurality of sides of the mask frame; and
a first waterproof membrane arranged on a surface of the first support stick facing the mask sheet.

2. The mask assembly of claim 1, further comprising:
a second support stick arranged between the first support stick and the mask sheet, the second support stick intersecting the first support stick; and
a second waterproof membrane arranged on a surface of the second support stick.

3. The mask assembly of claim 2, wherein the second waterproof membrane is arranged on a surface of the second support stick that faces the mask sheet.

4. The mask assembly of claim 2, wherein
the first support stick comprises a groove overlapping the second support stick, and
at least a portion of the second support stick is arranged in the groove.

5. The mask assembly of claim 1, further comprising:
an alignment stick arranged on the mask frame, the alignment stick being adjacent to the mask sheet and parallel to one of the plurality of sides of the mask frame.

6. The mask assembly of claim 1, wherein the first waterproof membrane comprises a self-assembled monolayer.

7. An apparatus for manufacturing a display device, the apparatus comprising:
a mask assembly; and
a deposition source facing the mask assembly and configured to spray a deposition material toward the mask assembly in a first direction,
wherein the mask assembly comprises:
a mask frame comprising a plurality of sides and an opening;
a first support stick arranged on the mask frame to overlap the opening, the first support stick extending in a direction parallel to one of the plurality of sides of the mask frame;
a mask sheet arranged on the first support stick, the mask sheet extending in a direction parallel to one of the plurality of sides of the mask frame; and
a first waterproof membrane arranged on a surface of the first support stick facing the first direction.

8. The apparatus of claim 7, wherein the mask assembly further comprises:
a second support stick arranged between the first support stick and the mask sheet, the second support stick intersecting the first support stick; and
a second waterproof membrane arranged on a surface of the second support stick.

9. The apparatus of claim 8, wherein the second waterproof membrane is arranged on a surface of the second support stick that faces the first direction.

10. The apparatus of claim 8, wherein in a cross-sectional view, the first support stick, the first waterproof membrane, the second support stick, the second waterproof membrane, and the mask sheet are sequentially arranged in the first direction.

11. The apparatus of claim 8, wherein
the first support stick comprises a groove overlapping the second support stick, and
at least a portion of the second support stick is arranged in the groove.

12. The apparatus of claim 7, wherein the mask assembly further comprises an alignment stick arranged on the mask frame, the alignment stick being adjacent to the mask sheet and parallel to one of the plurality of sides of the mask frame.

13. The apparatus of claim 7, wherein the first waterproof membrane comprises a self-assembled monolayer.

14. A method of manufacturing a display device, the method comprising:
arranging a mask assembly and a deposition source to face a substrate;
aligning the mask assembly to the substrate; and
depositing a deposition material on the substrate by spraying the deposition material from the deposition source toward the mask assembly in a first direction,
wherein the mask assembly comprises:
a mask frame comprising a plurality of sides and an opening;
a first support stick arranged on the mask frame to overlap the opening, the first support stick extending in a direction parallel to one of the plurality of sides of the mask frame;
a mask sheet arranged on the first support stick, the mask sheet extending in a direction parallel to one of the plurality of sides of the mask frame; and
a first waterproof membrane arranged on a surface of the first support stick facing the first direction.

15. The method of claim 14, wherein the mask assembly further comprises:
a second support stick arranged between the first support stick and the mask sheet, the second support stick intersecting the first support stick; and
a second waterproof membrane arranged on a surface of the second support stick.

16. The method of claim 15, wherein the second waterproof membrane is arranged on a surface of the second support stick that faces the first direction.

17. The method of claim 15, wherein in a cross-sectional view, the first support stick, the first waterproof membrane, the second support stick, the second waterproof membrane, and the mask sheet are sequentially arranged in the first direction.

18. The method of claim 15, wherein
the first support stick comprises a groove overlapping the second support stick, and
at least a portion of the second support stick is arranged in the groove.

19. The method of claim 14, wherein the mask assembly further comprises an alignment stick arranged on the mask frame, the alignment stick being adjacent to the mask sheet, and parallel to one of the plurality of sides of the mask frame.

20. The method of claim 14, wherein the first waterproof membrane comprises a self-assembled monolayer.
